(19) United States
(12) Patent Application Publication
(10) Pub. No.: US 2003/0162364 A1
(43) Pub. Date: Aug. 28, 2003

(54) Method of forming shallow trench isolation in a substrate

(76) Inventors: Ping-Wei Lin, Hsinchu (TW); Yao Sheng Yu, Hsinchu (TW); Ya-Lin Wang, Kaohsiung Hsien (TW)

Correspondence Address: BIRCH STEWART KOLASCH & BIRCH, PO BOX 747, FALLS CHURCH, VA, 22040-0747, US

(21) Appl. No.: 10/212,110

(22) Filed: Aug. 6, 2002

(30) Foreign Application Priority Data
Feb. 26, 2002 (TW) 91103436

(51) Int. Cl. H01L 21/76

(52) U.S. Cl. 438/424; 438/400; 438/404

(57) ABSTRACT

A method of forming shallow trench isolation (STI) in a substrate. A shield layer is formed on part of the substrate. Using the shield layer as a mask, part of the substrate is removed to form a trench in the substrate. A first insulation layer is formed in part of the trench, where the trench remains an opening. The first insulation layer is partially etched back to leave a remaining first insulation layer at the bottom of the trench and to expose the sidewall of the trench above the remaining first insulation layer. The trench is filled up with a second insulation layer extending onto the shield layer. A planarization is performed on the second insulation layer, where the shield layer serves as a stop layer for the planarization. Thus, a void-free trench isolation area is formed in a substrate.

### BACKGROUND OF THE INVENTION

1. Field of the Invention

The present invention relates to the semiconductor manufacturing process, and more particularly, to a method for forming shallow trench isolation (STI) in a substrate.

2. Description of the Related Art

Semiconductor device geometry continues to decrease in size, providing more devices per fabricated wafer. Currently, some devices are being fabricated with less than 0.25 μm spacing between features; in some cases there is as little as 0.18 μm spacing between features, which often takes the form of a trench.

An isolation technique called shallow trench isolation (STI) has been introduced to the fabrication of devices to reduce the size. Isolation trenches are formed in a substrate between features, such as transistors. FIGS. 1A˜1B are schematic views of a traditional STI process.

In FIG. 1A, a substrate 10 such as a silicon wafer is provided. A shield layer 11 composed of a pad oxide layer 12 and a SiN layer 14 is formed on part of the substrate 10. The shield layer 11 serves as a stacked mask for defining an isolation area in the substrate 10.

In FIG. 1B, using the shield layer 11 as a mask, part of the substrate 10 is etched to form a trench 15. A thin oxide film 16 is conformably formed on the side and the bottom of the trench 15 by thermal oxidation. The thin oxide film 16 serves as a linear layer, whose thickness is about 180˜220 Å. A trench-filling material such as a SiO₂ layer 18 is deposited in the trench 15 by high-density plasma chemical vapor deposition (HDP-CVD).

FIG. 1C illustrates that a void may form as a trench with a narrow gap is filled with the traditional process. For example, when the width of the trench 15 is smaller than 0.15 μm and/or the aspect ratio of the trench is greater than 4, a void 20 is easily formed in a SiO₂ layer 19 with the traditional process. Such a void seriously affects device reliability and yield, and hinders semiconductor device geometry from shrinking.

### SUMMARY OF THE INVENTION

The object of the present invention is to provide a method of forming shallow trench isolation (STI) in a substrate.

Another object of the present invention is to lower the aspect ratio of a trench during a deposition process to fill that trench with a void-free manner.

In order to achieve these objects, a method of forming shallow trench isolation (STI) in a substrate is provided. A shield layer is formed on part of the substrate. Using the shield layer as a mask, part of the substrate is removed to form a trench in the substrate. A first insulation layer is formed in part of the trench and on the shield layer. The first insulation layer is partially etched back to leave a remaining first insulation layer at the bottom of the trench and to expose the sidewall of the trench above the remaining first insulation layer. The trench is filled up with a second insulation layer extending onto the shield layer. A planarization is performed on the second insulation layer, where the shield layer serves as a stop layer for the planarization.

Moreover, when the aspect ration of the trench is high, before forming the second insulation layer, a third insulation layer can be formed in part of the trench having the remaining first insulation layer. Subsequently, the third insulation layer is partially etched back to leave a remaining third insulation layer on the remaining first insulation layer and to expose the sidewall of the trench above the remaining third insulation layer. Thus, the aspect ratio of the trench can be further reduced.

The present invention improves on the prior art in that the present method uses at least two times deposition to fill the trench with insulation material. Thus, the invention can prevent voids forming during the trench-filling process, thereby raising reliability and yield, and ameliorating the disadvantages of the prior art.

### BRIEF DESCRIPTION OF THE DRAWINGS

The present invention can be more fully understood by reading the subsequent detailed description in conjunction with the examples and references made to the accompanying drawings, wherein:

FIGS. 1A˜1B are sectional views according to the traditional STI process;

FIG. 1C is a schematic view, according to the traditional STI process, that forms a void in a trench; and

FIGS. 2˜8 are sectional views according to an embodiment of the present invention.

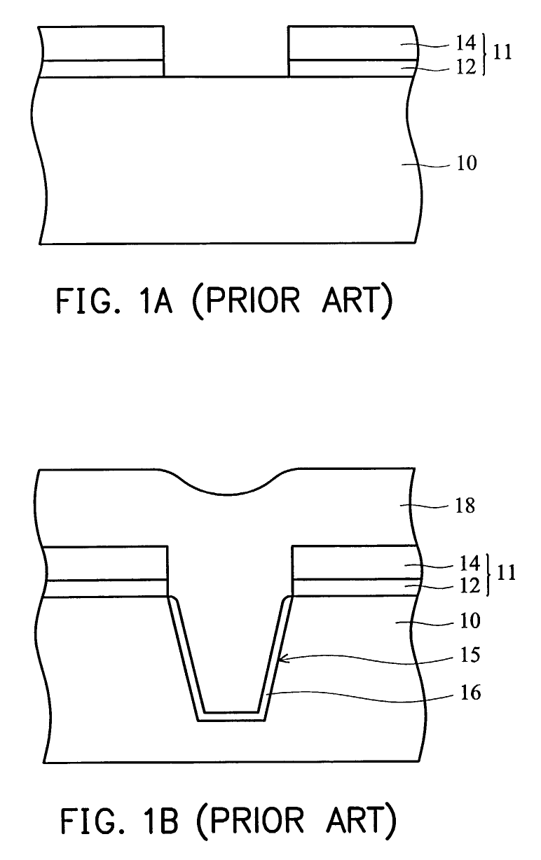

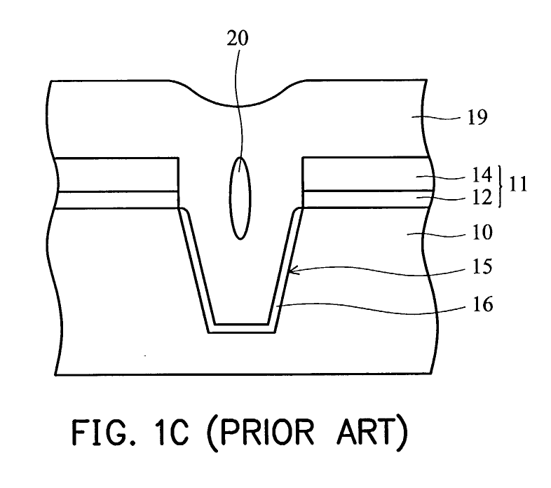

### DETAILED DESCRIPTION OF THE INVENTION

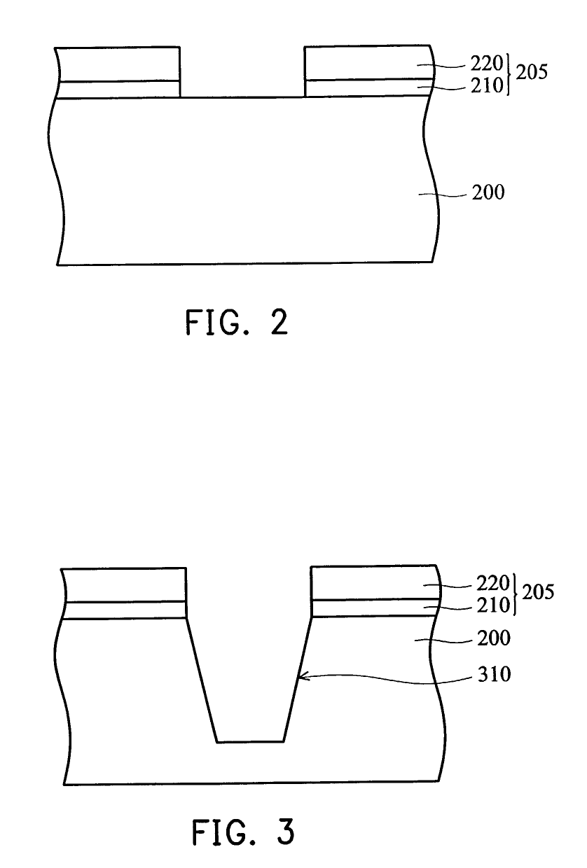

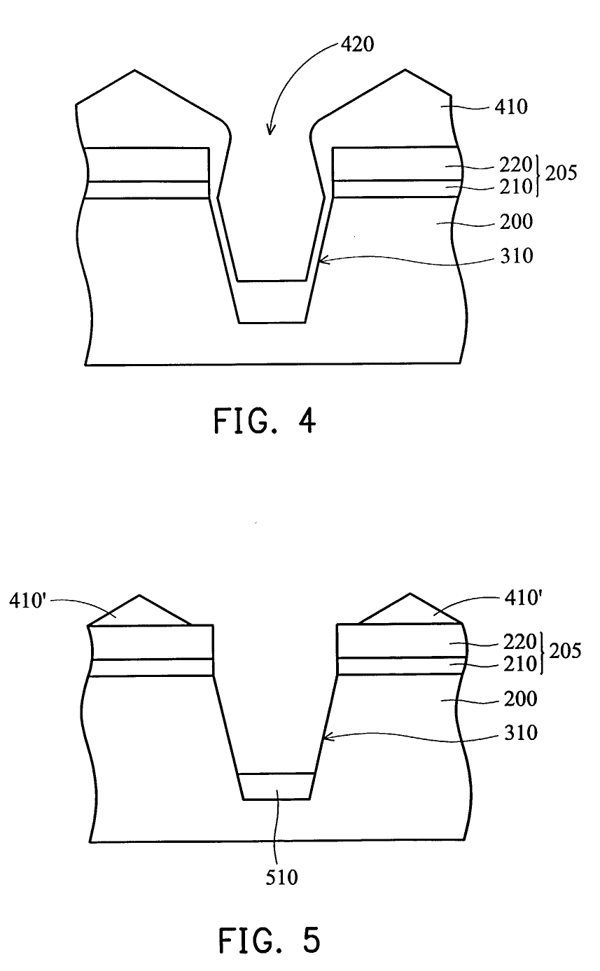

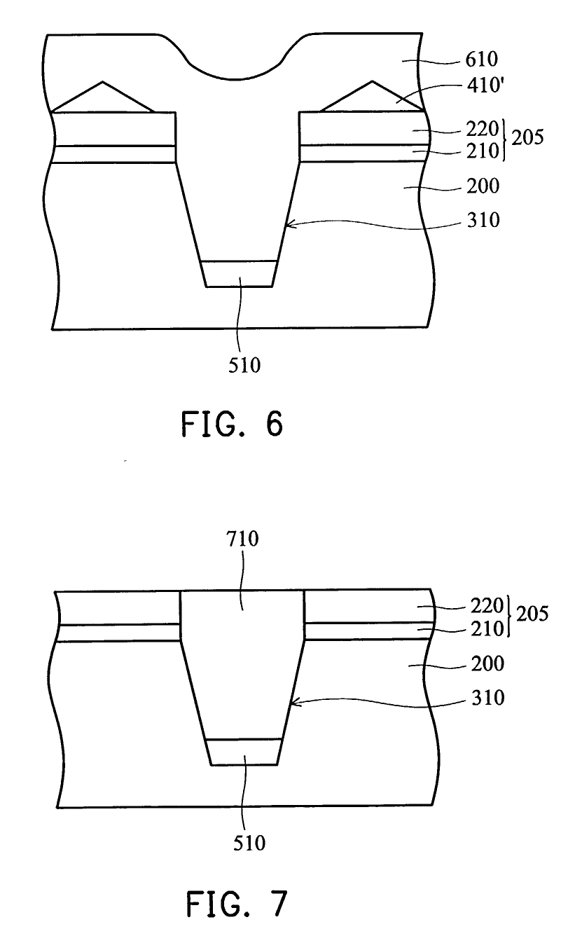

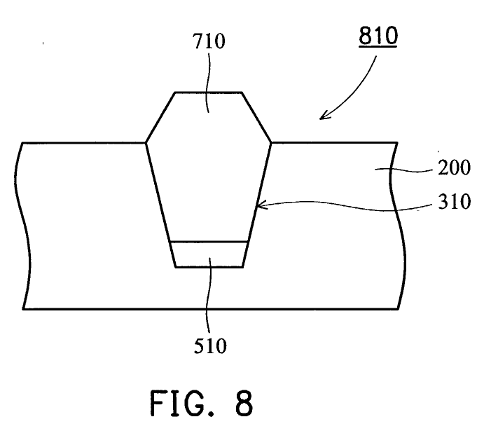

FIGS. 2˜8 are sectional views according to an embodiment of the present invention.

In FIG. 2, a substrate 200 such as a silicon wafer is provided. A shield layer 205 preferably composed of a pad oxide layer 210 and a SiN layer 220 is formed on part of the substrate 200. The pad oxide layer 210 can be a SiO₂ layer formed by thermal oxidation or deposition. The SiN layer 220 can be formed by deposition. The thickness of the pad oxide layer 210 is about 50˜200 Å. The thickness of the SiN layer 220 is about 1200˜1700 Å. The shield layer 205 serves as a stacked mask for defining an isolation area in the substrate 200.

In FIG. 3, using the shield layer 205 as a mask, part of the substrate 200 is etched to form a trench 310. Moreover, a thin oxide film (not shown) can be conformably formed on the side and the bottom of the trench 310 by thermal oxidation. The thin oxide film serves as a linear layer, whose thickness is about 180˜220 Å. In order to simplify the illustration, the thin oxide film is not shown in FIGS. 2-8.

In FIG. 4, a trench-filling material such as a SiO₂ layer 410 is deposited in part of the trench 310 and on the shield layer 205 by high-density plasma chemical vapor deposition (HDP-CVD). It should be noted that the trench 310 is not filled up with the SiO₂ layer 410. That is, the trench 310 has an opening 420 remaining. The conditions of the HDP-CVD are, for example, using SiH₄ and O₂ as process gas and the ratio of SiH₄/O₂ is about 1.5˜2, at a temperature of about 550˜650° C., a pressure of about 5 m torr and, in-situ, performing Ar gas bombardment. Moreover, the HDP-CVD can cooperate with time-mode to ensure that trench 310 is not filled up with the SiO₂ layer 410.

In FIG. 5, using wet etching, the first insulation layer 410 is partially etched back to leave a remaining first insulation layer 510 at the bottom of the trench 310 and to expose the sidewall of the trench 310 above the remaining first insulation layer 510. The wet etching may be BOE etching or HF etching. Since the thickness of first insulation layer 410 located at the bottom of the trench 310 is thicker than the first insulation layer 410 located at the lateral of the trench 310, the first insulation layer 410 located at the bottom of the trench 310 retains a certain thickness after the wet etching. Thus, this step reduces the aspect ratio of the trench 310 to promote the subsequent deposition. Additionally, after the first insulation layer 410 is partially etched, portions of the first insulation layer 410, symbolized by 410′, may remain on part of the shield layer 205.

Moreover, when the aspect ratio of the trench is very high, the following steps, similar to FIGS. 4˜5, can be performed at least one cycle to reduce the aspect ratio further. A third insulation layer (not shown) can be formed in part of the trench 310 having the remaining first insulation layer 510. Subsequently, the third insulation layer (not shown) is partially etched back to leave a remaining third insulation layer (not shown) on the remaining first insulation layer 510 and to expose the sidewall of the trench 310 above the remaining third insulation layer (not shown). The partial etching back of the third insulation layer (not shown) can be wet etching. Consequently, the aspect ratio of the trench 310 can be reduced further.

In FIG. 6, using HDP-CVD or TEOS-CVD, the trench 310 is filled up with a second insulation layer 610 extending onto the shield layer 205. The second insulation layer 610 is, for example, a SiO₂ layer. Because of the lower aspect ratio of the trench 310 according to the present method, the void-free deposition is easily achieved.

In FIG. 7, a planarization such as chemical mechanical polishing (CMP) is performed on the second insulation layer 610 to get a smoothed second insulation layer 710, wherein the shield layer 205 serves as a stop layer for the planarization.

In FIG. 8, the SiN layer 220 is removed by, for example, a phosphoric acid solution. The pad oxide layer 210 is removed by, for example, a HF solution. Thus, a void-free STI profile 810 is formed.

Thus, the present invention provides a method of forming void-free STI in a substrate, and a method of lowering the aspect ratio of a trench during a deposition process to fill that trench. Additionally, the present invention significantly improves the reliability of the product and achieves the goal of IC shrinkage.

Finally, while the invention has been described by way of example and in terms of the above preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming shallow trench isolation in a substrate, comprising the steps of:
(a) forming a shield layer on part of the substrate;
(b) using the shield layer as a mask, removing part of the substrate to form a trench in the substrate;
(c) forming a first insulation layer in part of the trench and on the shield layer, wherein the trench retains an opening;
(d) partially etching back the first insulation layer to leave a remaining first insulation layer at the bottom of the trench and to expose the sidewall of the trench above the remaining first insulation layer;
(e) filling up the trench with a second insulation layer extending onto the shield layer; and
(f) performing a planarization on the second insulation layer, wherein the shield layer serves as a stop layer for the planarization.

2. The method according to claim 1, further comprising, after the step (d), at least one cycle of the steps of:
(d1) forming a third insulation layer in part of the trench having the remaining first insulation layer; and
(d2)partially etching back the third insulation layer to leave a remaining third insulation layer on the remaining first insulation layer and to expose the sidewall of the trench above the remaining third insulation layer.

3. The method according to claim 1, wherein the shield layer is composed of a pad oxide layer and a SiN layer.

4. The method according to claim 3, wherein the pad oxide layer is a SiO₂ layer formed by thermal oxidation.

5. The method according to claim 3, wherein the SiN layer is formed by deposition.

6. The method according to claim 1, further comprising, after the step (b), the step of:
forming a conformal linear layer on the side and the bottom of the trench.

7. The method according to claim 1, wherein the first insulation layer is a SiO₂ layer formed by HDP-CVD.

8. The method according to claim 1, wherein the second insulation layer is a SiO₂ layer formed by HDP-CVD.

9. The method according to claim 1, wherein the second insulation layer is a SiO₂ layer formed by TEOS-CVD.

10. The method according to claim 2, wherein the third insulation layer is a SiO₂ layer formed by HDP-CVD.

11. The method according to claim 1, wherein the planarization is chemical mechanical polishing (CMP).

12. The method according to claim 1, wherein the method of partial etching back of the first insulation layer is wet etching.

13. The method according to claim 2, wherein the method of partial etching back of the third insulation layer is wet etching.
